(19) United States
(12) Patent Application Publication
(10) Pub. No.: US 2019/0337840 A1
(43) Pub. Date: Nov. 7, 2019

(54) THIN LAYER DEPOSITION PROCESS

(71) Applicant: SAINT-GOBAIN GLASS FRANCE, COURBEVOIE (FR)

(72) Inventors: Nisita WANAKULE, PARIS (FR); Constance MAGNE, PARIS (FR); Clément BOTTOIS, COMPIEGNE (FR)

(21) Appl. No.: 16/302,006

(22) PCT Filed: May 22, 2017
(86) PCT No.: PCT/FR2017/051243

§ 371 Date: Nov. 15, 2018

(30) Foreign Application Priority Data
May 24, 2016 (FR) 1654635

(51) Int. Cl. C03C 17/00; G02B 1/18; C23C 14/18; C23C 14/20; C23C 14/58

(52) U.S. Cl. CPC C03C 17/002; G02B 1/18; C23C 14/185; C23C 14/205; C03C 17/3689; C23C 14/5853; C03C 2217/71; C03C 2218/154; C03C 2218/322; C23C 14/5813

(57) ABSTRACT

A process for obtaining a material includes a substrate coated with a photocatalytic coating, the process including depositing on the substrate, by sputtering, a stack of thin layers successively including a first layer of titanium metal having a thickness of from 1 to 3 nm, an intermediate layer of at least partially oxidized titanium having a thickness of from 0.5 to 5 nm, and a second layer of titanium metal having a thickness of from 2 to 5 nm; and oxidizing the stack, with the aid of a heat treatment by laser radiation, wherein the stack is in contact with an oxidizing atmosphere.

The invention relates to a process for obtaining a material comprising a substrate coated with a photocatalytic coating and also to the substrate coated with a photocatalytic coating obtained in this way.

A process commonly employed on the industrial scale for the deposition of thin layers, in particular on a glass substrate, is the sputtering process, in particular enhanced by a magnetic field, referred to in this case as the “magnetron” process. In this process, a plasma is created under high vacuum in the vicinity of a target comprising the chemical elements to be deposited. The active entities of the plasma, on bombarding the target, tear off said elements, which are deposited on the substrate, forming the desired thin layer. This process is termed “reactive” when the layer consists of a material resulting from a chemical reaction between the elements torn from the target and the gas contained in the plasma. The major advantage of this process lies in the possibility of depositing, on the same line, a very complex stack of layers by successively making the substrate run under various targets, generally in one and the same device.

However, the deposition rate of the layers of oxide, such as titanium oxide, which is generally much lower than the deposition rate of metals, limits the production rate, which increases the production cost of the stacks comprising oxide layers deposited by sputtering. Application WO 2011/039488 describes a thin layer deposition process comprising a step of depositing an intermediate layer of metal, nitride or carbide and a step of oxidizing this intermediate layer using a rapid heat treatment, in particular by laser radiation. This process makes it possible to obtain metal oxide layers with higher production rates.

A laser treatment as described in WO 2011/039488 makes it possible to heat thin coatings to high temperatures, of the order of several hundred degrees, while preserving the underlying substrate. The treatment rates are of course preferably as high as possible, advantageously at least several meters per minute. To enable the high-speed treatment of substrates of large width, such as flat glass sheets of “jumbo” size (6 m×3.21 m) leaving float processes, it is necessary to have laser lines that are themselves very long (>3 m). Since the manufacture of monolithic optics enabling a single laser line to be obtained is not conceivable for such lengths, individual laser lines of smaller size (a few tens of centimeters) are generally combined together to form a long enough laser line.

The layers of metal that have to be oxidized during the laser treatment must in general have a minimum thickness in order to be able to achieve, after oxidation, the desired specifications of the product. For example, in order for a layer of titanium to have, once oxidized, the desired photocatalytic and optical properties, this layer advantageously has a thickness before oxidation of at least 5 nm. It is then difficult to carry out a complete and/or homogeneous oxidation of this layer, in particular at high run speeds. Specifically, the intensity variations of the laser may lead to differences in oxidation in certain zones, in particular at the zones of overlap of the individual laser lines. This phenomena, referred to as stitching, which is particularly exacerbated at high treatment rates, may give rise to visible defects on the final product, such as inhomogenous strips over the length of the substrate, which are not acceptable from the esthetic point of view. Furthermore, the high treatment rates that are desired from the point of view of the production cost may lead to an incomplete oxidation of the layer to be treated, which has the effect of increasing the residual light absorption of the coating after treatment.

The objective of the present invention is to overcome the aforementioned drawbacks. The Applicant has demonstrated that it was possible to improve the oxidation of a layer of titanium by laser treatment, in particular at high treatment rates, by separating the layer to be treated into two layers of titanium of equivalent total thickness which are separated by a layer of at least partially oxidized titanium.

Thus the present invention relates to a process for obtaining a material comprising a substrate coated with a photocatalytic coating, said process comprising:
a step of depositing on said substrate a stack of thin layers successively comprising a first layer of titanium metal having a thickness of from 1 to 3 nm, an intermediate layer of at least partially oxidized titanium having a thickness of from 0.5 to 5 nm, and a second layer of titanium metal having a thickness of from 2 to 5 nm; and
a step of oxidizing, with the aid of a heat treatment by laser radiation, wherein the stack is in contact with an oxidizing atmosphere.

The process according to the invention makes it possible to reduce the phenomena of stitching and/or the residual light absorption, in particular at high treatment rates, typically greater than 2 m/min, or greater than 3 m/min, or even greater than 4 m/min, or greater than 5 m/min. The presence of a partially oxidized intermediate layer between the two metal layers enables a more complete and/or more homogeneous oxidation of the metal layers.

The process according to the invention comprises a first step of depositing, on a substrate, a stack of thin layers comprising an intermediate layer of at least partially oxidized titanium between two layers of titanium metal. The layers of titanium metal are in direct contact with the intermediate layer of at least partially oxidized titanium. The first layer of titanium metal may be in direct contact with the substrate. However, in certain embodiments, other layers, such as a barrier layer to alkali metals for example based on silicon oxide, may be deposited between the substrate and the first layer of titanium metal. In general, no other layer is deposited on the second layer of titanium metal so that the photocatalytic layer of titanium oxide obtained at the end of the process according to the invention is the last layer of the coating in contact with the atmosphere.

The substrate is preferably a sheet of glass, of glass-ceramic or of a polymeric organic material. It is preferably transparent, colorless (it is then a clear or extra-clear glass) or colored, for example blue, green, gray or bronze. The glass is preferably of soda-lime-silica type but it can also be a glass of borosilicate or alumino-borosilicate type. The preferred polymeric organic materials are polycarbonate or polymethyl methacrylate or else polyethylene terephthalate (PET). The substrate advantageously exhibits at least one dimension greater than or equal to 1 m, or indeed 2 m and even 3 m. The thickness of the substrate generally varies between 0.5 mm and 19 mm, preferably between 0.7 and 9 mm, in particular between 2 and 8 mm, or indeed between 4 and 6 mm. The substrate can be flat or curved, or indeed flexible.

The glass substrate is preferably of the float glass type, that is to say capable of having been obtained by a process which consists in pouring the molten glass onto a bath of molten tin (“float” bath). In this case, the layer to be treated can be deposited both on the “tin” face and on the “atmosphere” face of the substrate. The terms “atmosphere” and “tin” faces are understood to mean the faces of the substrate which have respectively been in contact with the atmosphere prevailing in the float bath and in contact with the molten tin. The tin side contains a small superficial amount of tin which has diffused into the structure of the glass. The glass substrate can also be obtained by rolling between two rolls, a technique which makes it possible in particular to print patterns on the surface of the glass.

The first and second layers of titanium metal are deposited by sputtering. The deposition of metal layers has the advantage of allowing very high deposition rates compared to a deposition of an oxide layer. The intermediate layer may also be deposited by sputtering. Since this layer is very thin, the production rate of the stack will only be slightly impacted by the deposition of the oxidized titanium layer. The intermediate layer may also be obtained by partial oxidation of the first layer of titanium metal for example by exposing the substrate to air or to an oxidizing plasma after the deposition of the first layer of titanium metal.

The first layer of titanium metal has a thickness of from 1 to 3 nm, preferably from 1 to 2 nm, and the second layer of titanium metal has a thickness of from 2 to 5 nm, preferably from 2 to 4 nm. Specifically, too thick a first layer of titanium metal leads to a significant delamination of the coating during the heat treatment. Furthermore, too thick a second layer of titanium metal may impair the effectiveness of the oxidation of the first layer of titanium metal. The sum of the thicknesses of the first and second layers of titanium metal is preferably greater than or equal to 4 nm, or indeed greater than or equal to 5 nm in order to obtain, after heat treatment, a photocatalytic coating having a satisfactory activity.

The intermediate layer of at least partially oxidized titanium preferably has a thickness of from 0.5 to 3 nm, more preferentially from 0.5 to 2 nm.

The intermediate layer of at least partially oxidized titanium may be a layer of optionally substoichiometric titanium oxide. The latter will be denoted by TiOₓ. According to a specific embodiment, the value of x is preferably less than or equal to 1.8. In this case, the intermediate layer participates in the absorption of the laser radiation and thus makes it possible to improve the activation of the final photocatalytic layer. According to another specific embodiment, the value x is preferably greater than or equal to 1.8, in particular the layer of at least partially oxidized titanium is a layer of titanium oxide TiO₂. This embodiment has the advantage of enabling a more complete oxidation of the stack and of thus reducing the residual absorption thereof.

The process according to the invention also comprises a step of oxidizing the stack. The oxidation of the stack, in particular of the layers of titanium metal, is carried out by heat treatment using a laser, the stack being in contact with an oxidizing atmosphere. The oxidizing atmosphere is preferably air, in particular at atmospheric pressure. If necessary, the oxygen content of the atmosphere may be increased in order to further promote the oxidation of the intermediate layer.

The heat treatment makes it possible, in a single step, to oxidize the metal titanium to titanium oxide and to obtain a photocatalytic layer, which is therefore at least partially crystallized. The layer of titanium oxide obtained after heat treatment is preferably at least partially crystallized in the anatase phase, it being possible for the rutile phase to optionally be present too.

The heat treatment by laser radiation has the advantage of having a very high heat exchange coefficient, typically of greater than 400 W/(m²·s). The power per unit area of the laser radiation at the intermediate layer is even preferably greater than or equal to 20 or 30 kW/cm². This very high energy density makes it possible, at the intermediate layer, to reach the desired temperature extremely rapidly (generally in a time of less than or equal to 1 second) and consequently to accordingly limit the duration of the treatment, the heat generated then not having the time to diffuse within the substrate.

Thus, each treated point of the stack is preferably subjected to the heat treatment for a period of time generally of less than or equal to 1 second, or indeed 0.5 second. Owing to the very high heat exchange coefficient associated with the process according to the invention, even the part of the glass located 0.5 mm from the intermediate layer is generally not subjected to temperatures above 100° C. Preferably, the temperature of the substrate during the heat treatment does not exceed 100° C., in particular 50° C. This is in particular the temperature on the face opposite the face on which the intermediate layer is deposited. This temperature may be measured for example by pyrometry.

This process also makes it possible to incorporate a laser treatment device on the existing continuous production lines. The laser can thus be incorporated into a layer deposition line, for example a magnetic-field-enhanced (magnetron process) sputtering deposition line. In general, the line comprises devices for handling the substrates, a deposition unit, optical control devices and stacking devices. The substrates run, for example on conveyor rollers, successively in front of each device or each unit. The laser is preferably located immediately after the layer deposition unit, for example at the outlet of the deposition unit. The coated substrate can thus be treated in-line after the layer has been deposited, at the outlet of the deposition unit and before the optical control devices, or after the optical control devices and before the substrate stacking devices. It is also possible, in some cases, to carry out the heat treatment according to the invention within the vacuum deposition chamber. The laser is then incorporated into the deposition unit. For example, the laser can be introduced into one of the chambers of a sputtering deposition unit.

Whether the laser is outside the deposition unit or incorporated thereinto, these “in-line” or “continuous” processes are preferable to a process involving off-line operations, in which it would be necessary to stack the glass substrates between the deposition step and the heat treatment.

However, processes involving off-line operations can have an advantage in the cases where the heat treatment according to the invention is carried out in a place different from that where the deposition is carried out, for example in a place where the conversion of the glass is carried out. The radiation device can thus be incorporated into lines other than the layer deposition line. For example, it can be incorporated into a line for the manufacture of multiple glazings (in particular double or triple glazings) or into a line for the manufacture of laminated glazings. In these various cases, the heat treatment according to the invention is preferably carried out before the multiple or laminated glazing is produced.

The laser radiation preferably results from at least one laser beam forming a line (known as “laser line” in the continuation of the text) which simultaneously irradiates the entire width of the substrate. The in-line laser beam can in particular be obtained using focusing optical systems. In order to be able to simultaneously irradiate very wide substrates (>3 m), the laser line is generally obtained by combining several individual laser lines. The thickness of the individual laser lines is preferably between 0.01 and 1 mm. Their length is typically between 5 mm and 1 m. The individual laser lines are generally juxtaposed side-by-side in order to form a single laser line in such a way that the entire surface of the stack is treated. Each individual laser line is preferably positioned perpendicularly to the run direction of the substrate.

The laser sources are typically laser diodes or fiber lasers, in particular fiber, diode or else disk lasers. Laser diodes make it possible to economically achieve high power densities, with respect to the electrical supply power, for a small space requirement. The space requirement of fiber lasers is even smaller, and the linear power density obtained can be even higher, for a cost, however, which is greater. The term “fiber lasers” is understood to mean lasers in which the place where the laser light is generated is spatially removed from the place to which it is delivered, the laser light being delivered by means of at least one optical fiber. In the case of a disk laser, the laser light is generated in a resonator cavity in which the emitting medium, which is in the form of a disk, for example a thin disk (approximately 0.1 mm thick) made of Yb:YAG, is found. The light thus generated is coupled in at least one optical fiber directed toward the place of treatment. The laser can also be a fiber laser, insofar as the amplification medium is itself an optical fiber. Fiber or disk lasers are preferably optically pumped using laser diodes. The radiation resulting from the laser sources is preferably continuous.

The wavelength of the laser radiation, and thus the treatment wavelength, is preferably within a range extending from 800 to 1300 nm, in particular from 800 to 1100 nm. High-power laser diodes which emit at one or more wavelengths chosen from 808 nm, 880 nm, 915 nm, 940 nm or 980 nm have proved to be particularly well suited. In the case of a disk laser, the treatment wavelength is, for example, 1030 nm (emission wavelength for a Yb:YAG laser). For a fiber laser, the treatment wavelength is typically 1070 nm.

Preferably, the absorption of the stack at the wavelength of the laser radiation is greater than or equal to 20%, in particular 30%. The absorption is defined as being equal to the value of 100%, from which the transmission and the reflection of the layer are subtracted.

In order to treat the entire surface of the coated substrate, a relative movement is created between, on the one hand, the substrate coated with the layer and the laser line. The substrate can thus be moved, in particular so as to run translationally past the stationary laser line, generally below but optionally above the laser line. This embodiment is particularly advantageous for a continuous treatment. Preferably, the difference between the respective speeds of the substrate and the laser is greater than or equal to 2 meters per minute, indeed 3 and even 4, 5, 8 or 10 meters per minute, so as to ensure a high treatment rate.

The substrate can be moved using any mechanical conveying means, for example using belts, rollers or trays moving translationally. The conveying system makes it possible to control and regulate the rate of movement. If the substrate is made of a flexible polymeric organic material, it may be moved using a film advance system in the form of a succession of rollers.

Of course, all the relative positions of the substrate and of the laser are possible, as long as the surface of the substrate can be suitably irradiated. Usually, the substrate will be positioned horizontally but it can also be positioned vertically or according to any possible inclination. When the substrate is positioned horizontally, the laser is generally positioned so as to irradiate the upper face of the substrate. The laser can also irradiate the lower face of the substrate. In this case, it is necessary for the support system for the substrate, optionally the system for conveying the substrate when the latter is moving, to allow the radiation to pass in the zone to be irradiated. This is the case, for example, when conveying rollers are used: since the rollers are separate entities, it is possible to position the laser in a zone located between two successive rollers.

When both faces of the substrate are to be treated, it is possible to employ a number of lasers located on either side of the substrate, whether the latter is in a horizontal, vertical or any inclined position.

The present invention also relates to a substrate coated with a stack of thin layers successively comprising a first layer of titanium metal having a thickness of from 1 to 3 nm, preferably from 1 to 2 nm, an intermediate layer of at least partially oxidized titanium having a thickness of from 0.5 to 5 nm, preferably from 0.5 to 3 nm, or indeed from 0.5 to 2 nm, and a second layer of titanium metal having a thickness of from 2 to 5 nm, preferably from 2 to 4 nm. This substrate is intended to undergo an oxidation using a heat treatment by laser radiation, the stack being in contact with an oxidizing atmosphere, in order to obtain a substrate coated with a photocatalytic coating.

The present invention also relates to a substrate coated with a photocatalytic coating capable of being obtained by the process according to the invention. The substrate obtained according to the invention is preferably incorporated into a glazing. The glazing can be single or multiple (in particular double or triple), insofar as it can comprise several glass sheets providing a gas-filled space. The glazing can also be laminated and/or tempered and/or hardened and/or curved.

The face of the substrate opposite the face on which the stack is deposited, or where appropriate a face of another substrate of the multiple glazing, may be coated with another functional layer or with a stack of functional layers. It may in particular be layers or stacks having a thermal function, in particular solar-protection or low-emissivity layers or stacks, for example stacks comprising a silver layer protected by dielectric layers. It may also be a mirror layer, in particular based on silver. It may finally be a lacquer or an enamel intended to opacify the glazing in order to make a wall cladding panel therefrom, known as spandrel glass. The spandrel glass is positioned on the wall at the sides of non-opacified glazing and makes it possible to obtain walls that are entirely glazed and homogeneous from an esthetic point of view.

Other layers or stacks located on the face of the substrate opposite the face on which the oxide layer is deposited may see their properties improved owing to the heat treatment according to the invention. These may in particular be properties linked to a better crystallization of functional layers, for example of silver layers. It has thus been observed, in particular in the case of substrates made of glass having a thickness of at most 6 mm, that the oxidation heat treatment according to the invention was also able to reduce the emissivity and/or the resistivity of low-emissivity stacks containing at least one silver layer.

According to one embodiment of the invention, a stack of thin layers comprising as described above, comprising an intermediate layer of at least partially oxidized titanium between two layers of titanium metal is therefore deposited on one face of the substrate, and a stack of low-emissivity layers comprising at least one silver layer is deposited on the other face of said substrate, then said intermediate layer is treated using at least one laser radiation so that the emissivity or the resistivity of the low-emissivity stack is reduced by at least 3%. The reductions in emissivity or in resistivity are at least 3%, or indeed 5% and even 10%. It is thus possible, using a single heat treatment, to improve the emissivity properties of a low-emissivity stack and to obtain a photocatalytic layer. This is made possible by the fact that the laser radiation has only partly been absorbed by the titanium layers of the stack and the substrate, so that the low-emissivity stack located on the other face receives a portion of the energy of the radiation, which it uses to improve the crystallization properties of the or each silver layer. The product obtained has a self-cleaning, photocatalytic function on one face, which will therefore tend to be oriented toward the outside of the building, and a thermal insulation function on the other face, which will therefore tend to be oriented toward the inside of the building.

The invention is illustrated with the help of the following nonlimiting exemplary embodiments.

### EXAMPLES

Three samples (I1 to I3) comprising a photocatalytic coating, obtained by the process according to the invention, were prepared as follows.

A stack of thin layers consisting successively of a first layer of titanium metal, an intermediate layer of titanium oxide TiO₂, and a second layer of titanium metal is deposited on a clear soda-lime-silica glass substrate.

The layers of titanium metal are deposited by sputtering using a titanium target in an argon plasma. The intermediate layer of titanium oxide TiO₂ is also deposited by sputtering using a TiO₂ target in an argon plasma.

The samples are treated using an in-line laser, obtained by juxtaposition of several individual lines, emitting radiation with a wavelength of 1030 nm, past which the coated substrate runs translationally. The samples I1 and I2 were treated with a run speed of 2 m/min, whilst the sample I3 was treated with a run speed of 3 m/min.

By way of comparison, the samples (R1 to R3) comprising a photocatalytic coating obtained by laser treatment of a coating consisting respectively of a single 5 nm layer of titanium metal, of a 6 nm layer of titanium oxide surmounted by a 4 nm layer of titanium metal, and of a 6 nm layer of titanium metal surmounted by a 6 nm layer of titanium oxide were prepared. The samples (R1 to R3) were treated with a run speed of 2 m/min.

The “stitching” phenomenon was evaluated in reflection on a black background and in transmission on a white background by an entrained observer for each of the samples treated.

Table 1 below summarises the features of each of the samples and the results of the evaluation of the “stitching” phenomenon. The observations of the “stitching” phenomenon were denoted as follows: “x” indicates visible marks, “∘” indicates very light marking visible after searching, and “⊚” indicates an absence of visible marks.

| | Stack (nm) | | | Treatment | Stitching | |
|---|---|---|---|---|---|---|
| Sample | Ti | TiO₂ | Ti | rate (m/min) | Reflection | Transmission |
| R1 | — | — | 5 | 2 | X | X |
| R2 | — | 6 | 4 | 2 | X | ◯ |
| R3 | 6 | 6 | — | 2 | Not measured | |
| | | | | | (substantial delamination) | |
| I1 | 2 | 3 | 3 | 2 | ◯ | ⊚ |
| I2 | 2 | 1.6 | 3.5 | 2 | ⊚ | ⊚ |
| I3 | 1.5 | 1.5 | 3.5 | 3 | ⊚ | ⊚ |

The photocatalytic activity was also measured for each of the samples. The samples according to the invention have a photocatalytic activity that is comparable to that of the references R1 and R2.

1. A process for obtaining a material comprising a substrate coated with a photocatalytic coating, said process comprising:
depositing on said substrate, by sputtering, a stack of thin layers successively comprising a first layer of titanium metal having a thickness of from 1 to 3 nm, an intermediate layer of at least partially oxidized titanium having a thickness of from 0.5 to 5 nm, and a second layer of titanium metal having a thickness of from 2 to 5 nm; and
oxidizing said stack, with the aid of a heat treatment by laser radiation, wherein the stack is in contact with an oxidizing atmosphere.

2. The process as claimed in claim 1, wherein the substrate is a glass sheet.

3. The process as claimed in claim 1, wherein the intermediate layer of at least partially oxidized titanium is a layer of TiOₓ, x being greater than or equal to 1.8.

4. The process as claimed in claim 1, wherein the intermediate layer of at least partially oxidized titanium is a layer of TiO₂.

5. The process as claimed in claim 1, wherein the intermediate layer of at least partially oxidized titanium has a thickness of from 0.5 to 2 nm.

6. The process as claimed in claim 1, wherein the first layer of titanium metal and the second layer of titanium metal each have a thickness of from 1 to 5 nm.

7. The process as claimed in claim 1, wherein the first layer of titanium metal has a thickness of from 1 to 2 nm and the second layer of titanium metal has a thickness of from 2 to 4 nm.

8. The process as claimed in claim 1, wherein a run speed of the substrate during the heat treatment by laser radiation is greater than or equal to 2 m/min.

9. The process as claimed in claim 1, wherein the laser radiation has a wavelength of between 800 and 1300 nm.

10. The process as claimed in claim 1, wherein a power per unit area of the laser radiation at the intermediate layer is greater than or equal to 20 kW/cm².

11. The process as claimed in claim 1, wherein the laser radiation results from at least one laser beam forming a line that simultaneously radiates all or some of the width of the substrate.

12. A material comprising a substrate coated with a stack of thin layers successively comprising a first layer of titanium metal having a thickness of from 1 to 3 nm, an intermediate layer of at least partially oxidized titanium having a thickness of from 0.5 to 5 nm, and a second layer of titanium metal having a thickness of from 2 to 5 nm.

13. The material as claimed in claim 12, wherein the intermediate layer of at least partially oxidized titanium has a thickness of from 0.5 to 2 nm.

14. The material as claimed in claim 12, wherein the first layer of titanium metal has a thickness of from 1 to 2 nm and the second layer of titanium metal has a thickness of from 2 to 4 nm.

15. The material as claimed in claim 12, wherein the intermediate layer of at least partially oxidized titanium is a layer of TiO₂.

16. The process as claimed in claim 9, wherein the laser radiation has a wavelength of between 800 and 1100 nm.

17. The process as claimed in claim 10, wherein the power per unit area of the laser radiation at the intermediate layer is greater than or equal to 30 kW/cm².
